(19) United States
(12) Patent Application Publication
(10) Pub. No.: US 2026/0147950 A1
(43) Pub. Date: May 28, 2026

(54) METHOD AND APPARATUS FOR GENERATING CONCEPTUAL DESIGN FOR MOBILITY APPARATUS

(71) Applicants: HYUNDAI MOTOR COMPANY, Seoul (KR); KIA CORPORATION, Seoul (KR); Konkuk University Industrial Cooperation Corp, Seoul (KR)

(72) Inventors: Jeong A YANG, Hwaseong-si (KR); Woo Suk JUNG, Hwaseong-si (KR); Tae Yun CHOI, Hwaseong-si (KR); Keun Seok LEE, Hwaseong-si (KR); Eu Gene HWANG, Hwaseong-si (KR); Jae Woo LEE, Seoul (KR); Maxim TYAN, Seoul (KR); Min Ji KIM, Seoul (KR)

(21) Appl. No.: 19/365,848

(22) Filed: Oct. 22, 2025

(30) Foreign Application Priority Data
Nov. 28, 2024 (KR) 10-2024-0174169

(51) Int. Cl. G06F 30/15

(52) U.S. Cl. CPC G06F 30/15

(57) ABSTRACT

A method and an apparatus for generating conceptual design for mobility apparatus. The method includes: generating problem definition data according to a requirement specification of a user; generating function data according to functional decomposition for each aircraft mission based on the requirement specification and the problem definition data; extracting element data of a main configuration of the aircraft based on design concept data searched for based on the required function data and databased external data; and generating matrix data having airframe configuration data of the aircraft based on a combination of the element data of the main configuration.

### CROSS-REFERENCE TO RELATED APPLICATION

This application claims priority to and the benefit of Korean Patent Application No. 10-2024-0174169, filed on Nov. 28, 2024, the disclosure of which is incorporated herein by reference in its entirety.

### TECHNICAL FIELD

The present disclosure relates to a method and apparatus for generating a conceptual design for a mobility apparatus. More specifically, the present disclosure relates to a method and apparatus for generating a conceptual design for a mobility apparatus that reduces development costs and development time by quickly deriving a conceptual configuration satisfying design and operational characteristics of a new aircraft manufactured through low-volume, high-mix production.

### BACKGROUND

With the advance of technologies, various transportation mobility apparatuses are emerging. In order to improve ground traffic congestion and address urban environment deterioration, advanced air mobility (AAM) apparatuses are being actively developed. The AAM apparatuses may move to a specific point within a complex urban area and provide services linked with other types of mobility apparatuses, such as ground mobility apparatuses.

An AAM aircraft may be different from an existing aircraft in terms of design requirements and operational and mission characteristics. In a life cycle cost (LCC) of an aircraft, a cost in an initial concept design stage of the aircraft is small, but the ease of design change may be high. A large proportion of the life cycle cost may be determined in the initial concept design stage.

In some cases, in a concept design of the AAM, there may be substantially no development needs, a baseline configuration that is the basis of development, or design experts. Therefore, when a conceptual configuration can be developed based on an airframe design reflecting a user's requirements in the initial concept design stage, an airframe design considering integration with an eco-friendly propulsion system, and a level of technological progress, development costs and time may be reduced.

### SUMMARY

The present disclosure is directed to providing a method and apparatus for generating a conceptual design for a mobility apparatus that reduces development costs and development time by quickly deriving a conceptual configuration satisfying design and operational characteristics of a new aircraft manufactured through low-volume, high-mix production.

According to one aspect of the subject matter described in this application, a method for generating a conceptual design for a mobility apparatus includes generating problem definition data based on a requirement specification of a user, generating function data according to functional decomposition for a mission of the mobility apparatus based on the requirement specification and the problem definition data, extracting element data of a main configuration of the mobility apparatus based on (i) design concept data that have been searched for based on the function data and (ii) external data, and generating matrix data including airframe configuration data of the mobility apparatus based on a combination of the element data of the main configuration.

Implementations according to this aspect can include one or more of the following features. For example, the problem definition data can include a design requirement and a manufacturing process requirement of the mobility apparatus that are generated based on analyzing the requirement specification of the user, and a performance evaluation index of the airframe configuration data for each of the design requirement and the manufacturing process requirement, wherein the performance evaluation index indicates a contribution of the airframe configuration data to each of the design requirement and the manufacturing process requirement.

In some implementations, generating the problem definition data can include, based on the airframe configuration data corresponding to the mobility apparatus that is different in design and operation from a legacy aircraft, generating the problem definition data from the requirement specification according to at least one of (i) reduction of hazardous substance emission, (ii) low noise, (iii) certification challenges of the mobility apparatus, (iv) use of new technology, and (v) a novel airframe configuration.

In some examples, the mission defined in the function data can be classified based on at least one of a flight section or a flight behavior of the mobility apparatus, where the function data can include (i) functions of the mobility apparatus according to the mission, (ii) configuration elements of airframe components in the mobility apparatus related to the functions, and (iii) technology elements related to the configuration elements.

In some implementations, the external data can include a database including at least one of competitive aircraft data, technology data, product data, or configuration classification data, where the competitive aircraft data can include configuration of a competitive aircraft, a specification of the competitive aircraft, performance of the competitive aircraft, technology elements applied to the competitive aircraft, or development plan data of the competitive aircraft. The technology data can include technology data available for the mobility apparatus, the product data can include product information related to propulsion components of the mobility apparatus, and the configuration classification data can include configuration information related to configuration elements of airframe components.

In some implementations, the database can interconnect external data that satisfy the functions of the aircraft according to the mission and that include the competitive mobility apparatus data, the technology data, the product data, and the configuration classification data.

In some implementations, extracting the element data of the main configuration can include extracting the element data of the main configuration from the design concept data and the external data based on contribution data according to a performance evaluation index provided in the problem definition data, where the contribution data can include a contribution to the performance evaluation index for each configuration element of the design concept data and the external data.

In some implementations, generating the matrix data can include: generating examination data by combining evaluations of the element data of the main configuration based on a performance evaluation index provided in the problem definition data; and selecting the airframe configuration data from the combination of the element data of the main configuration based on the examination data according to the performance evaluation index.

In some implementations, the method can further include, after generating the matrix data, classifying the airframe configuration data of the matrix data based on a configuration group, and outputting the airframe configuration data. In some examples, classifying the airframe configuration data can include classifying the airframe configuration data (i) based on a configuration similarity between pieces of the airframe configuration data, or (ii) based on configurations that satisfy a predetermined condition in a dissimilarity between the configurations of the airframe configuration data.

According to another aspect, an apparatus is configured to generate a conceptual design for a mobility apparatus, where the apparatus includes at least one processor; and a non-transitory memory coupled to the at least one processor and storing instructions that, based on being executed by the at least one processor, perform operations including: generating problem definition data based on a requirement specification of a user, generating function data according to functional decomposition for a mission of the mobility apparatus based on the requirement specification and the problem definition data, extracting element data of a main configuration of the mobility apparatus based on (i) design concept data that have been searched for based on the function data and (ii) external data, and generating matrix data including airframe configuration data of the mobility apparatus based on a combination of the element data of the main configuration.

Implementations of the apparatus according to this aspect can include one or more of the features of the method describe above.

### BRIEF DESCRIPTION OF THE DRAWINGS

The above and other objects, features and advantages of the present disclosure will become more apparent to those of ordinary skill in the art by describing example implementations thereof in detail with reference to the accompanying drawings.

FIG. 1 is a diagram schematically illustrating modules related to an example of an apparatus for providing a conceptual design for an aircraft.

FIG. 2 is a diagram illustrating an example of a structured database.

FIG. 3 is a flowchart illustrating an example of a method for generating a conceptual design for an aircraft.

FIG. 4 is a diagram illustrating an example of a process related to providing the conceptual design for an aircraft.

FIG. 5 is a diagram illustrating an example of performance evaluation items of a performance evaluation index.

FIG. 6 is a diagram illustrating an example of function data according to functional decomposition.

FIG. 7 is a diagram illustrating an example of extraction of element data of a main configuration.

FIG. 8 is a diagram illustrating an example of examination of each piece of element data of a main configuration.

FIG. 9 is a diagram illustrating an example of matrix data.

FIG. 10 is a diagram illustrating an example of a distribution of the number of detailed configurations used to generate formal similarity.

FIG. 11 is a diagram illustrating an example of the formal similarity.

FIGS. 12A to 12C are diagrams illustrating an example of a similarity distribution for classifying a configuration group.

FIG. 13 is a flowchart illustrating an example of a process for selecting a conceptual design for an aircraft.

FIG. 14 is a diagram illustrating an example of a process of filtering the airframe configuration data.

FIG. 15 is a diagram illustrating an example of a weight and rank for each item of a performance evaluation index acquired through hierarchical analysis.

### DETAILED DESCRIPTION

Hereinafter, one or more example implementations of the present disclosure will be described in detail with reference to the accompanying drawings so that those skilled in the art can easily implement the present disclosure. However, the present disclosure can be implemented in various different ways, and is not limited to the implementations described therein.

Hereinafter, implementations of the present disclosure will be described with reference to the accompanying drawings.

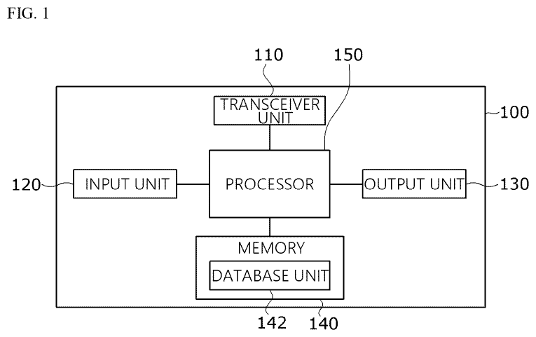

Hereinafter, an apparatus for providing a conceptual design for an aircraft used in an implementation of the present disclosure will be described with reference to FIG. 1. FIG. 1 is a diagram schematically illustrating modules related to the apparatus for providing a conceptual design for an aircraft according to the implementation of the present disclosure. In the present disclosure, the apparatus is described as providing a conceptual design for an aircraft, but the apparatus can also be referred to as a device that provides a conceptual design for a mobility apparatus moving to a predetermined place or location.

In some implementations, an apparatus 100 for providing a conceptual design for a mobility apparatus such as an aircraft can generate and manage a conceptual design for an aircraft, and select the conceptual design for an aircraft that satisfies a search request from a user in response to the search request. The aircraft for which the conceptual configuration is provided can be not only an existing legacy aircraft, but also a new air mobility, such as an AAM aircraft, but is not limited thereto. The new air mobility can be different from the legacy aircraft in terms of a propulsion scheme, take-off and landing scheme, fuselage structure, and the like. Hereinafter, the providing apparatus 100 of a conceptual design for an aircraft can simply be called a providing apparatus for the convenience of description.

The providing apparatus 100 can include a transceiver 110, an input unit 120, an output unit 130, a memory 140, and a processor 150. The providing apparatus 100 can be a computing device and can be a device that holds software for generating and selecting a conceptual configuration for an aircraft in a non-transitory storage medium. The providing apparatus 100 can be provided by a local computer or a cloud server.

The transceiver 110 can transmit and receive data to and from an external device, support mutual communication to acquire external data in the present disclosure, and exchange data with a device that holds or manages the external data. The device can be, for example, a plurality of servers that manage various types of information related to an aircraft. The server can be, for example, an external device that provides academic paper information, news, patent information, and the like, or an external device that manages a website that provides aircraft-related airframe structures, propulsion components, authentication information, and the like. The external data can include at least one of competitive aircraft data, technology data, product data, or configuration classification data. This data will be described in detail later.

The input unit 120 can be an input interface that receives a user's request or input data. The interface can be a hardware or software interface. The hardware interface can be, for example, a keyboard and a mouse, and a software interface can be a graphical user interface of a display provided by the output unit 130.

The output unit 130 can output a response to the user's request or input data visually, audibly, or tactilely. The output unit 130 can be, for example, a display, a speaker, or a tactile sensing device.

The memory 140 can store an application and various types of data for operating the providing apparatus 100, and load the application or read or record the data in response to a request from the processor 150.

In the present disclosure, the memory 140 can include a database unit 142 that is used to generate or select a conceptual configuration for an aircraft. The database unit 142 can hold external data related to the conceptual configuration for an aircraft. The database unit 142 can receive the information from an external server that provides information related to an aircraft, for example, and extract or process the external data from the information according to a setting of the user or processor 150.

The external data can include, for example, at least one of the competitive aircraft data, technology data, product data, or configuration classification data, but is not limited thereto, and the external data can have various types of information related to a conceptual configuration for an aircraft. The competitive aircraft data can include the configuration of a competitive aircraft, a specification of the competitive aircraft, performance of the competitive aircraft, technology elements applied to the competitive aircraft, or development plan data for the competitive aircraft.

In the case of an AAM, for example, the configuration of a competitive aircraft can be an aircraft configuration related to a vectored thrust including a tilting rotor, a lift and cruise scheme including rotors responsible for thrust and lift, a multicopter having rotors arranged in the same direction, and the like. Further, the configuration of the competitive aircraft can include various configurations according to a take-off and landing scheme of the AAM. Examples of the take-off and landing scheme of the AAM can include Vertical Take-off and Landing (VTOL), Short Take-off and Landing (STOL), and Conventional Take-off and Landing (CTOL). The configuration of the competitive aircraft can include any configuration related to fixed-wing aircraft without rotors and rotary-wing aircraft. The configuration of the competitive aircraft is not limited to the above, and can include any configuration related to existing fixed-wing aircraft and existing rotary-wing aircraft, that is, legacy aircraft. The configuration of the competitive aircraft can include configuration information related to configuration elements of airframe components. The airframe components can include main wings, tail wings, fuselage, wing-fuselage coupling, and windows, but are not limited to. Data related to the configuration of the competitive aircraft will be described in detailed information of configuration classification data to be described below.

The technology data can include technology already applied to the aircraft or new technology data available for the aircraft. For example, the technology data can include technology related to an AAM and a legacy aircraft in a competitive aircraft and an actual product. The technology data can be technology information of each component constituting the aircraft.

The product data can include product information related to the propulsion components of the aircraft. The propulsion components can include, for example, a powertrain of the aircraft, units that generate thrust and lift, and a control surface. The powertrain can be, for example, an electric battery including a rechargeable secondary battery, a fuel cell, an internal combustion engine, a turbo engine, a generator, or a solar cell. In the case of the AAM, the unit that generates thrust and lift is, for example, a propeller, a motor, an actuator including an inverter, an actuator including a turbo engine, and a wing, but is not limited to. In addition, the product data can include data related to a location, number, arrangement, type, and operation of the actuator. The type of actuator can be, for example, an open type or a closed type. The open type can be a type in which a propeller is placed outside the fuselage, and the closed type can be a type in which a propeller or a fan that generates a fluid flow is disposed inside the wing. The number and location of propulsion components such as actuators can be, for example, 2-to-6/On Wing, 2-to-6/Below Wing, 2-to-6/Tail Boom Front, 2-to-6/On Stabilizer, 6+/On Wing, 6+/Below Wing, 6+/On Tail Boom Front, or 6+/On Stabilizer, but are not limited thereto.

Configuration classification data can include configuration information related to configuration elements of the airframe components. The airframe components can be, for example, main wings, tail wings, fuselage, wing-fuselage integration, and windows. In the case of the main wing, the configuration classification data can be, for example, configuration data related to Straight wing, Tandem wing, and Box wing. In the case of the tail, the configuration classification data can be, for example, configuration data related to conventional Tail, T-Tail, Canard, and Tailless. In the case of the fuselage, the configuration classification data can be, for example, Tube Configuration, Streamlined Configuration, and Double Bubble Configuration. The wing-fuselage integration can be a blended wing body (BWB), and the BWB can have an integral configuration in which the fuselage and the wing are coupled as a single configuration, unlike a structure in which the fuselage and the wing are separated. In some examples, the configuration classification data can be related to the presence or absence of the BWB. In the case of the window, the configuration classification data can be, for example, configuration data related to Conventional Windows, Overhead Panoramic Windows, and Windowless Design.

The database unit 142 can further include information related to technology maturity for each piece of technology data and each piece of product data. The technology maturity can be assigned to each component belonging to the technology data and the product data. The technology maturity can indicate, for example, a technology level related to the development of the component and the commercialization of the component. The technology level can be set to have a high grade according to a development progress level and a level of practical use. For example, for the technology maturity, a technology readiness level (TRL) divided into levels 1 to 9 can be utilized.

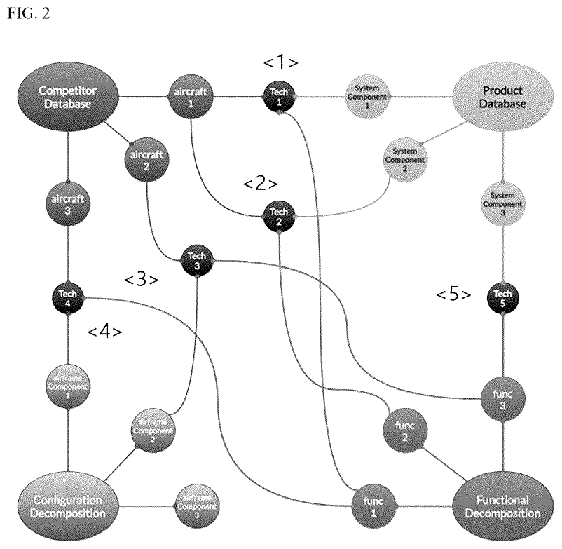

The database unit 142 can be constructed to interconnect external data that satisfies detailed functions of the aircraft according to a mission, as illustrated in FIG. 2. FIG. 2 is a diagram illustrating a structured database.

The mission can be classified based on at least one of a flight section and behavior of the aircraft. The mission according to the flight section can be a task that can occur throughout an entire flight section, such as take-off, cruising, landing, and emergency flight. The mission according to the behavior can be related to a specific operation of the flight, such as flight attitude control, turbulence and airflow coping control, flight path optimization control, collision avoidance control, and energy consumption optimization control. The mission can be performed by executing at least one detailed function, and the detailed function can be a function that is used or requested to perform the mission. The detailed function can include a plurality of layers. Specifically, the detailed function can include a higher-level function for executing the mission and at least one lower-level function for realizing the higher-level function. For example, in the case of cruising, the higher-level function of the detailed function can be lift provision and stability provision. A lower-level function for providing the lift can be a function related to generating the lift and implementing lift/drag efficiency. A lower-level function for providing the stability can be a function related to longitudinal stability, lateral stability, and directional stability.

The interconnection of external data satisfying the detailed function will be described in the example of FIG. 2. Data related to Competitor, Product, Configuration, and Function represent competitor aircraft data, product data/new technology data, configuration classification data, and detailed function data, respectively. In FIG. 2, the data related to Configuration and Function can be referred to as configuration decomposition and functional decomposition.

In the case of <1>, the data related to competitor, product, and function can be connected through node 1 (Tech 1). Tech 1 is a technology related to system component 1 (for example, a hydrogen fuel cell) of a product used in Aircraft 1 in a competitor database, and detailed functions of function 1 can be performed through the technology. In the case of <2>, the data related to the competitor, product, and function can be connected through node 2 (Tech 2). Tech 2 is a technology related to system component 2 (for example, a hydrogen fuel cell) of a product used in Aircraft 1 in the competitor database, and detailed functions of function 2 can be performed through the technology.

In the case of <3>, data related to Competitor, Configuration Decomposition, and Function can be connected through node 3 (Tech 3). Tech 3 is a technology related to Airframe Component 2 (for example, the fuselage) used in Aircraft 2 in the competitor database, and detailed functions of function 3 can be performed through the technology. In the case of <4>, the data related to Competitor, Configuration Decomposition, and Function can be connected through node 4 (Tech 4). Tech 4 is a technology related to Airframe Component 1 (for example, a wing) used in Aircraft 3 in the competitor DB, and the detailed functions of function 1 can be performed through the technology.

In the case of <5>, the data related to the function and product can be connected through node 5 (Tech 5). Tech 5 is a technology that has not been used in any competitive aircraft, and the detailed function of function 3 can be performed by system component 3 (for example, propulsion) corresponding to a new technology.

In relation to the present disclosure, the processor 150 can perform processing for generating or selecting the conceptual configuration for the aircraft using applications, instructions, and data stored in the memory 140. Specifically, in relation to the present disclosure, the processor 150 can execute processing for generating problem definition data according to a user's requirement specification. The processor 150 can perform processing for generating required function data according to the functional decomposition for each aircraft mission based on the requirement specification and the problem definition data. Further, the processor 150 can implement processing for extracting design concept data searched for based on the required function data and element data of the main configuration of the aircraft based on databased external data. The processor 150 can execute processing for generating matrix data having the airframe configuration data of the aircraft based on a combination of the element data of the main configuration.

The processor 150 can be implemented as a single processing module, for example. In another example, the processing according to the above-described matters can be distributed and processed in a plurality of processing modules, and in the present disclosure, the plurality of processing modules can also be collectively referred to as the processor 150.

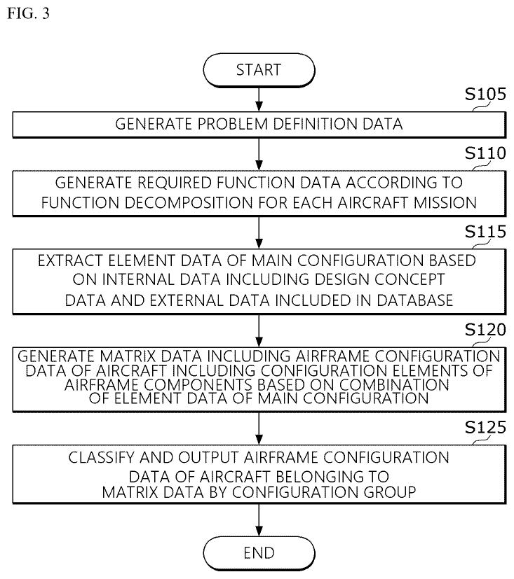

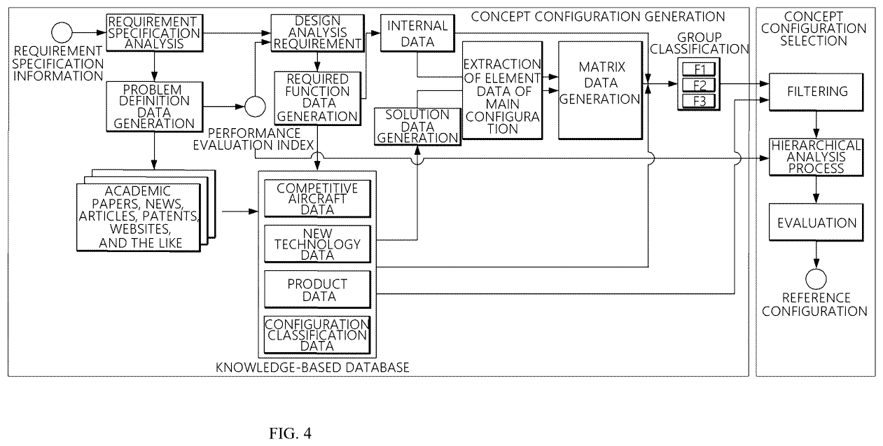

Hereinafter, a method according to an implementation of the present disclosure, that is, the method for generating a conceptual design for an aircraft, which is performed by the providing apparatus 100, will be described with reference to FIGS. 3 and 4. FIG. 3 is a flowchart of the method for generating a conceptual design for an aircraft according to the implementation of the present disclosure. FIG. 4 is a diagram illustrating an entire process related to providing the conceptual design for an aircraft according to the implementation of the present disclosure. In the present disclosure, each module of the providing apparatus 100 processes a process of the above method, but for the convenience of description, each module processing the process can be described as the providing apparatus 100.

First, the processor 150 of the providing apparatus 100 can generate the problem definition data according to a user's requirement specification (S105).

The problem definition data can include design requirements, aircraft manufacturing process requirements, and interpreted meanings provided by analyzing the user's requirement specification information input through the input unit 120. In the present disclosure, the requirement specification information can simply be called a requirement specification. The analysis of the requirement specification information can be performed by the user or the processor 150. With the processor 150, the providing apparatus 100 can analyze, for example, text of the requirement specification information input by the user through a learning model to generate the design requirements, the aircraft manufacturing process requirements, and the interpreted meanings.

Although the requirement specification information is a requirement for the conceptual configuration of the aircraft, the requirement specification information can be described in a non-specific manner. The requirement specification information can be described in an abstract and broad sense. Accordingly, the processor 150 can analyze abstract content of the requirement specification information and convert the abstract content into specific requirements to be reflected in the aircraft design. The specific requirements can be the design requirements, the aircraft manufacturing process requirements, and the interpreted meanings.

In an example of the generation of the problem definition data, the requirement specification information can be provided as follows. The requirement specification information can describe “A 50-seat commercial inter-regional electric-hybrid aircraft that can be commercialized in 2035/2040 is developed, and a roadmap for key technologies and regulatory aspects for this is identified. This development will accelerate and integrate the development of electric-hybrid aircraft and technologies, thereby helping to promote the growth of a sustainable and competitive aviation industry, as well as facilitating the growth of regulatory agencies, air traffic management, and energy source suppliers.” In addition, the requirement specification information can describe “The following is required for the aircraft: [1] The aircraft should have the lowest emission and noise levels among aircraft in the same class. [2] The aircraft should have technology for ensuring safety in an operation aspect. [3] The aircraft should have competitive operating costs. [4] The aircraft should secure improvements in the operation aspect compared to existing regional aircraft. [5] A current infrastructure should be used and maintained to the maximum extent possible.”

The illustrated requirement specification information can be converted into specific requirements, that is, the design requirements, the aircraft manufacturing process requirements, and the interpreted meanings, through semantic analysis of the described content. For example, for the design requirement, a requirement “Confirmation of certification criteria related to commercial 50-seat aircraft, and analysis of specifications and performance of similar 50-seat aircraft” can be generated based on the requirement specification information as in the above-described example. For the meaning interpretation, content “Confirmation of what it exactly means to ensure the safety in the operation aspect and what technology is related to this” can be generated based on the requirement specification information. For the manufacturing process requirements, a requirement “Confirmation of problems that occur when major technologies are integrated into the aircraft and presentation of a method for evaluating whether an integration method is optimal” can be generated based on the requirement specification information. As another example, the design requirements, the aircraft manufacturing process requirements, and the interpreted meanings can be generated to have combined items based on the requirement specification information.

For tracking by the user during a design process, the processor 150 can generate a checklist in specific items of illustrated problem definition data by user input or user request.

When airframe configuration data of an aircraft that requires different design and operation from a legacy aircraft is required for selection of a conceptual configuration of the aircraft, specific items in specific aspects can be derived from the requirement specification in the problem definition data. The aircraft different from the legacy aircraft can be, for example, a new air mobility or an AAM, but is not limited thereto. The specific aspect can be, for example, at least one of reduction of hazardous substance emission, low noise, certification challenges of the aircraft, use of new technology, and novel airframe configuration.

The problem definition data can include a performance evaluation index of the airframe configuration data for design requirements, manufacturing process requirements, interpreted meanings, and combinations thereof. The performance evaluation index can be generated by the user or the processor 150. The performance evaluation index can be provided to evaluate a contribution of the airframe configuration data to the design requirements, manufacturing process requirements, interpreted meanings, and combinations thereof. For the performance evaluation index, a scheme related to a figure of merit (FoM), for example, can be used. The performance evaluation index can include a plurality of performance evaluation items to evaluate the contribution of the airframe configuration data according to the aircraft design requirements, the aircraft manufacturing process requirements, and the interpreted meanings. The plurality of performance evaluation items can be arranged hierarchically to have multiple layers in a tree structure.

The performance evaluation index can be generated from the requirement specification without reference data, or can be generated by using reference data that satisfies the requirement specification based on the reference data. The performance evaluation index can be generated without items that are not related to the requirement specification. The performance evaluation index can not include items having determined evaluation criteria or evaluation values in the requirement specification. The performance evaluation index can be generated without items that do not have an obvious difference between conceptual configuration candidates. The performance evaluation index can be generated to have an appropriate number of performance evaluation items to reflect design requirements in the conceptual configuration of the aircraft.

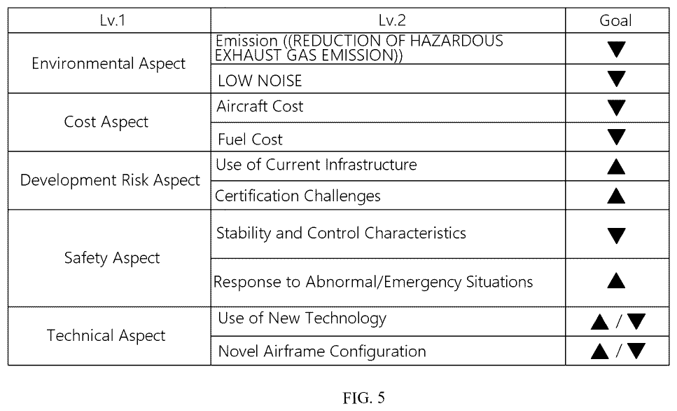

When airframe configuration data of an aircraft (for example, an AAM) that requires different design and operation from a legacy aircraft is required for selection of a conceptual configuration of the aircraft, the performance evaluation index can have performance evaluation items that differentiate the aircraft from the legacy aircraft in terms of an environmental aspect, a development risk aspect, and a technical aspect, as illustrated in FIG. 5. FIG. 5 is a diagram illustrating performance evaluation items of the performance evaluation index. In addition to the example of FIG. 5, the performance evaluation index can also have performance evaluation items related to visual appeal.

The environmental aspect can have, for example, performance evaluation items related to reduction of hazardous substance emission and low noise. The item related to reduction of hazardous substances can be, for example, a propulsion system that uses eco-friendly materials that can be reused and recycled and an eco-friendly energy source. The item related to the low noise can be noise generated by an airframe structure (vibration) and noise generated by the propulsion system. The development risk aspect can include, for example, performance evaluation items related to certification challenges of the aircraft and utilization of current infrastructure. The certification challenges can be certification approval risk due to low technology maturity and a unique configuration. The utilization of the infrastructure can be short take-off and landing aircraft characteristics and propulsion technology for utilization of small regional airports. The technical aspect can have, for example, performance evaluation items related to use of new technology and a novel airframe configuration. The performance evaluation items related to the visual appeal can be, for example, unconventional airframe configuration, boarding comfort, and new technologies that are visually noticeable.

Referring to FIGS. 3 and 4, the processor 150 of the providing apparatus 100 can generate the required function data according to the functional decomposition for each aircraft mission based on the requirement specification and the problem definition data (S110).

The mission can be classified based on at least one of a flight section and behavior of the aircraft. Description of the mission is omitted since the description has been described above with reference to FIG. 1.

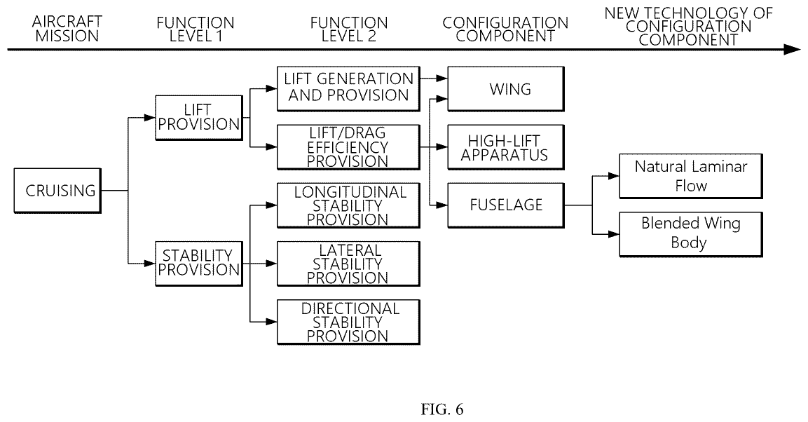

The required function data can include detailed functions of the aircraft according to the mission, configuration elements of the airframe components in the aircraft related to the detailed functions, and technology elements related to the configuration elements. The detailed functions can be functions that are used or requested to perform the mission. The detailed functions can include a plurality of layers. Specifically, the detailed function can include a higher-level function for executing the mission and at least one lower-level function for realizing the higher-level function. That is, the detailed functions can be hierarchically generated to have a plurality of levels in a tree structure, as illustrated in FIG. 6. FIG. 6 is a diagram illustrating required function data according to the functional decomposition.

FIG. 6 illustrates an example of a case in which the mission is cruising. Function level 1 corresponding to a higher-level function related to the cruising can be lift provision and stability provision. A lower-level function for lift provision at function level 2 can be a function related to lift generation and lift/drag efficiency implementation. Configuration elements of the airframe components related to lift generation and lift/drag efficiency implementation are commonly wings, and configuration elements of the airframe components related to the lift/drag efficiency implementation can additionally include a high-lift apparatus and the fuselage. The fuselage for an AAM can be associated with new technology elements having a natural laminar flow and a BWB.

Lower-level functions for the stability provision at function level 2 can be functions related to longitudinal stability, lateral stability, and directional stability. In some examples, each of such direction stabilities can be associated with corresponding airframe component configuration elements and new technology elements.

Referring back to FIGS. 3 and 4, the processor 150 can extract the design concept data searched for based on the required function data and element data of the main configuration of the aircraft based on the databased external data (S115).

The design concept data can be data related to the conceptual configuration of the aircraft designed or collected by the user. The design concept data can be acquired internally through brainstorming or concept sketching. The external data can be acquired from the database unit 142. The external data can include, but is not limited to, at least one of the competitive aircraft data, technology data, product data, or configuration classification data, and can have various types of information related to the conceptual configuration for the aircraft. Since the external data has been described with reference to FIG. 1, detailed description thereof will be omitted.

The processor 150 can select configuration element data that matches the required function data between the configuration element data of the aircraft included in the design concept data and the configuration element data of the external data as the element data of the main configuration. Information on configuration element data of a plurality of main configurations or a combination of the configuration element data can be referred to as a solution in the present disclosure, and the configuration element data can be referred to as a detailed configuration in the present disclosure. The selection of the element data from the design concept data corresponds to an internal search, and the selection of the element data from the external data can correspond to an external search.

Further, the processor 150 can extract the element data of the main configuration from the design concept data and the external data based on contribution data according to the performance evaluation index provided in the problem definition data. The contribution data can include a contribution to the performance evaluation index for each configuration element included in the design concept data and the external data.

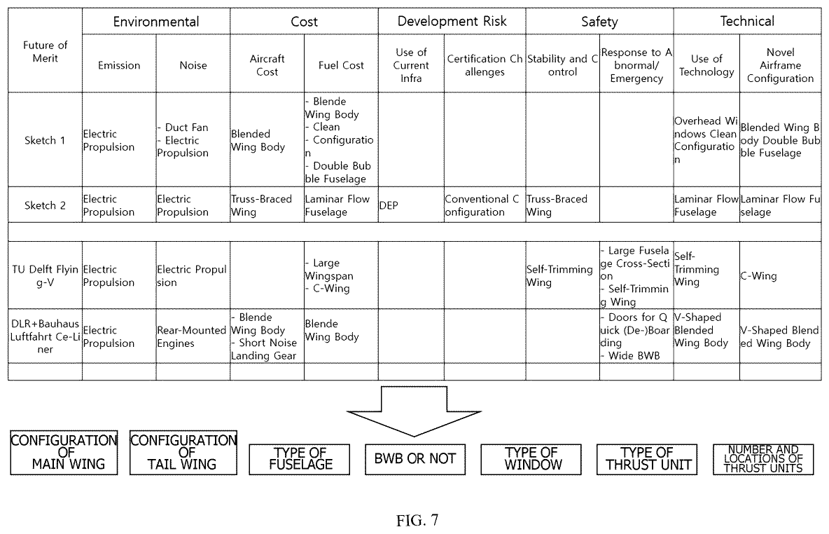

FIG. 7 is a diagram illustrating the extraction of the element data of the main configuration. In FIG. 7, the element data of the main configuration extracted by applying a performance evaluation index FoM to the design concept data and the external data is illustrated. Among contribution data for a plurality of configuration elements belonging to the above data, configuration element data satisfying a predetermined condition can be selected as the element data of the main configuration. In the example of FIG. 7, the element data of the main configuration can be extracted as configuration elements related to the configuration of a main wing, the configuration of a tail wing, a type of fuselage, presence or absence of the BWB, a type of window, a type of thrust unit, and the number and locations of thrust units.

In the example of FIG. 7, the configuration of main the wing can be, for example, a straight wing, a tandem wing, or a box wing. The configuration of the tail wing can be, for example, a conventional tail, a t-tail, a canard, or tailless. The type of fuselage can be, for example, a tube configuration, a streamlined configuration, or a double bubble configuration. The types of wings and windows can be, for example, conventional windows, overhead panoramic windows, or a windowless design. The type of thrust unit is a type of the actuator, and the type of the actuator can be, for example, an open type or a closed type. A location of the thrust, that is, a location of the actuator, can be, for example, On Wing, Below Wing, Beside Fuselage, on Tail Boom, on the Fuselage, or On Stabilizer.

The above-described details are only an example of the element data of the main configuration, and other element data can be extracted as the main configuration.

The element data of the main configuration can be generated in the form of a solution that contributes to the performance evaluation index, as illustrated in FIG. 7. When all solutions derived from the design concept data and the external data are utilized as conceptual configuration candidates, computing resources can be greatly consumed for selection of an optimal conceptual configuration. When the element data of the main configuration is extracted and the matrix data to be described below is generated, computing resources required for the matrix data can be reduced. Further, since aircraft with a similar design specification or requirements can have common characteristics, the extraction of the element data of the main configuration can be meaningful.

Referring to FIGS. 3 and 4 again, the processor 150 can generate matrix data having airframe configuration data of the aircraft based on the combination of element data of the main configuration (S120).

The processor 150 can select the airframe configuration data from the combination of element data of the main configuration based on examination data according to the performance evaluation index provided in the problem definition data. The examination data can be generated by combining the evaluation of element data of the main configuration according to the performance evaluation index. The selected airframe configuration data can be included in the matrix data.

The examination can be performed by the user or the processor 150, and the examination data can be generated as the evaluation result. An FoM contribution of each element of the main configuration can be used as the examination data. For example, when the contribution is good based on a most widely adopted solution in the competitive aircraft or the element data of the main configuration, +1 can be assigned. When the contribution is poor, −1 can be assigned, and when the contribution is not determined, 0 can be assigned.

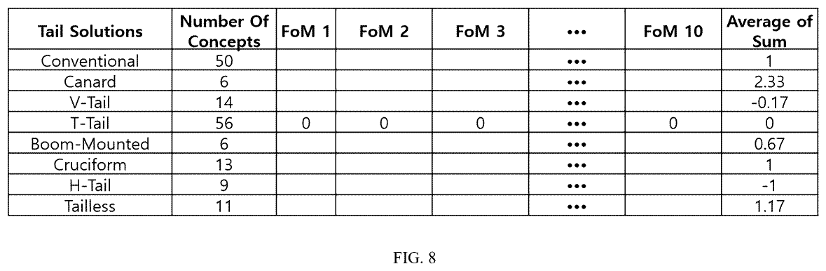

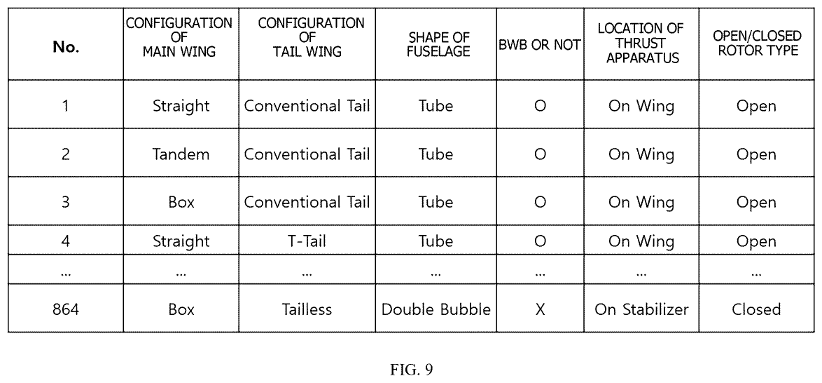

FIG. 8 is a diagram illustrating an examination of each piece of element data of the main configuration. In FIG. 8, since the number of concepts in a T-Tail configuration is the largest, the solution or element data of other main configurations is evaluated based on the T-Tail. When the contribution is good for each FoM item compared to the T-Tail, +1 is assigned. When the contribution cannot be determined, 0 is assigned, and when the contribution is poor, −1 is assigned. In FIG. 8, scores of respective solutions are summed, a solution with a positive value is selected, and the selected solution is included in the matrix data, as illustrated in FIG. 9. The element data of the main configurations listed by solution, for example, in No. 1 to No. 4 or a combination thereof, is provided as airframe configuration data, and the matrix data can be generated by tabulating the airframe configuration data. FIG. 9 is a diagram illustrating the matrix data. In the present disclosure, the matrix data can also be referred to as a morphological matrix.

Referring back to FIGS. 3 and 4, the processor 150 can classify and output the airframe configuration data belonging to the matrix data by configuration group (S125).

The processor 150 can classify the airframe configuration data based on a configuration similarity between the pieces of airframe configuration data, or classify the airframe configuration data based on the detailed configurations satisfying a predetermined condition in a dissimilarity between the detailed configurations constituting the airframe configuration data.

The detailed configuration can be the element data of the main configuration. In some examples, the element data can also be referred to as the solution described above. A configuration similarity between a plurality of detailed configurations derived from the design concept data and the external data through the internal search and external search is evaluated, and the configuration group can be classified based on a result of the evaluation. In some examples, the configuration similarity and the configuration group can be referred to as a formal similarity and a configuration family, respectively.

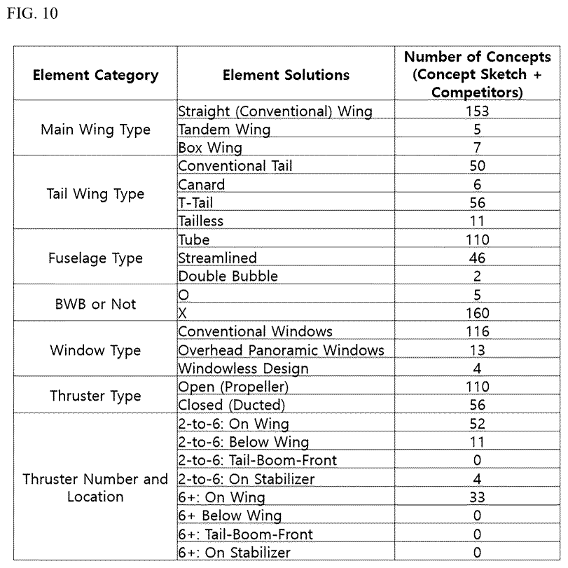

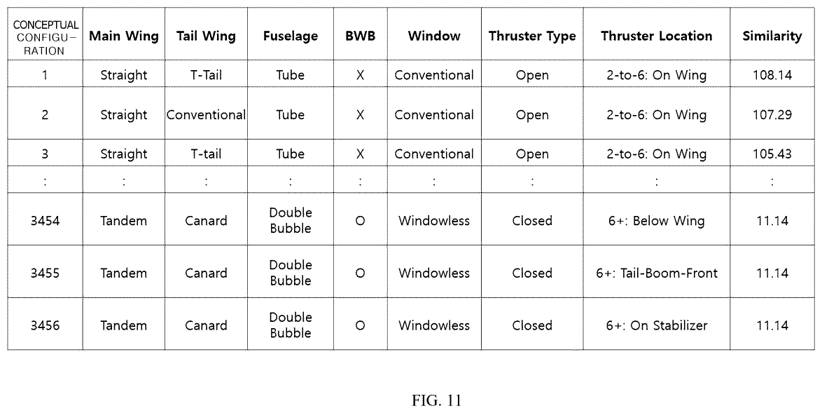

The formal similarity can be acquired for each of a plurality of conceptual configurations corresponding to the airframe configuration data that is a combination of the plurality of detailed configurations. The formal similarity of the conceptual configuration can be generated by dividing a sum of the numbers of concepts of the respective detailed configurations by the number of classifications for grouping the configuration data of the main configuration. In the examples of FIGS. 10 and 11, a formal similarity of conceptual configuration 1 is generated by dividing a sum of the numbers of concepts of detailed configurations including Straight Wing, T-Tail Wing, Tube Fuselage, BWB X, Conventional Window, Open Thruster, and 2-to-6 Thruster On Wing by 7 that is the number of classifications. In the examples of FIGS. 10 and 11, the formal similarity of conceptual configuration 1 can be obtained as (153+56+110+160+116+110+52)/7=108.14.

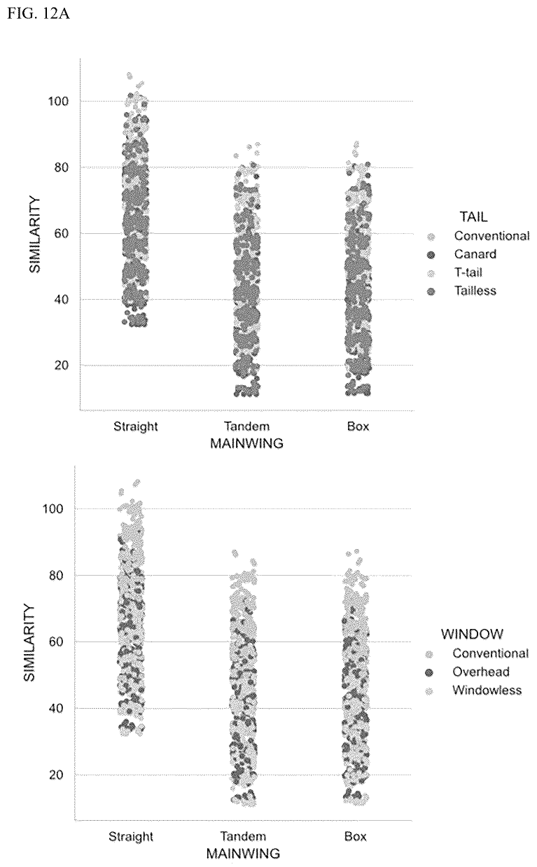

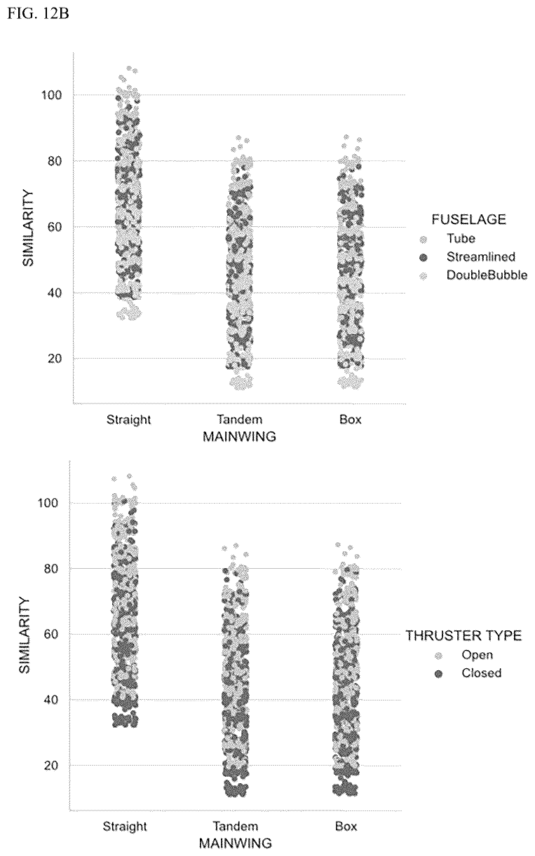

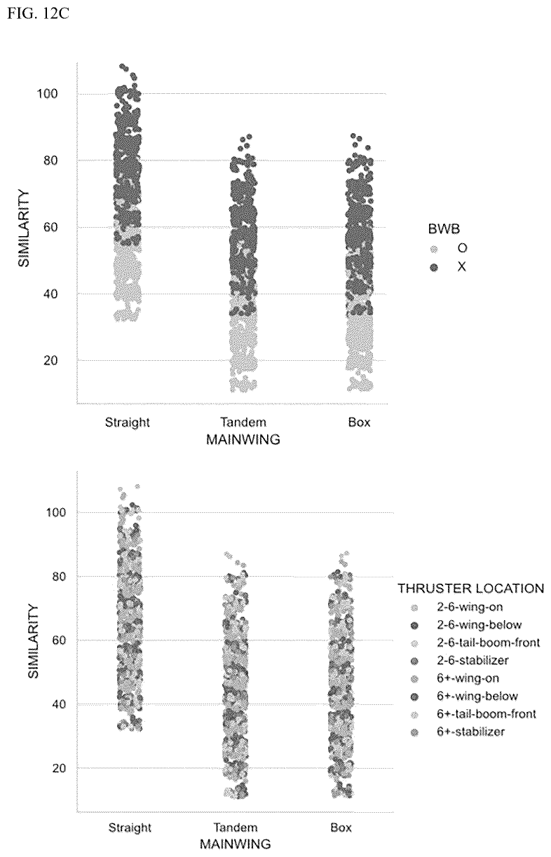

The processor 150 can generate a configuration family (or configuration group), based on a distribution based on the formal similarity. A distribution of the formal similarity according to FIGS. 10 and 11 is illustrated in FIGS. 12A to 12C. FIGS. 12A to 12C are diagrams illustrating similarity distributions for classifying configuration groups. Considering the formal similarity of FIGS. 12A to 12C, criteria for configuration families that satisfy predetermined conditions and exhibit a clear similarity difference are the configuration of the main wing (Conventional or Not Conventional) and BWB or not (BWB O or X). The criteria for the configuration families can include classifications and detailed configurations belonging to the classifications. The processor 150 can classify the airframe configuration data by configuration group according to the criteria, and provide the airframe configuration data of the aircraft classified by configuration group via the output unit 130. In some examples, the airframe configuration data of the aircraft can be the conceptual configuration of the aircraft. In the examples of FIGS. 10 to 12A to 12C, a configuration family F1 is a Straight Conventional Wing+BWB X of the configuration of the main wing, a configuration family F2 is a Tandem Wing/Box Wing+BWB X of the configuration of the main wing, and a configuration family F3 is BWB O.

Accordingly, since the evaluation of a large amount of airframe configuration data derived in operation S120 entails excessive tasks, it is efficient to identify common elements from candidate configurations and classify the elements into upper-level configuration family groups. Aircraft in the same family share the same or similar components or structures, so that high quality, short-term production, and labor reduction can be realized during a production process.

The airframe configuration data of the configuration group according to the implementation of FIG. 3 is managed in the database unit 142 and can be used for selection of the conceptual configuration to be described below.

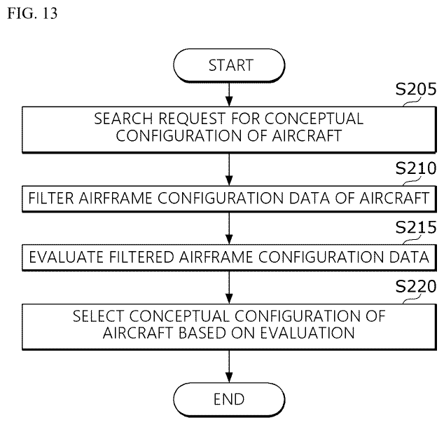

Hereinafter, a method according to the present disclosure, that is, a method for selecting a conceptual configuration for an aircraft, which is performed by the providing apparatus 100, will be described with reference to FIGS. 4 and 13. FIG. 13 is a flowchart of a process for selecting a conceptual design for an aircraft according to the present disclosure. In the present disclosure, each module of the providing apparatus 100 processes the process of the method, but for the convenience of description, each module that processes the process can be described interchangeably as the providing apparatus 100.

The processor 150 of the providing apparatus 100 can receive a user's search request for the conceptual configuration of the aircraft (S205).

The user can input, through the input unit 120, at least one of problem definition data, information related to at least a part of element data of the airframe configuration data related to the conceptual configuration, element information related to a design of the new air mobility, element data, and performance evaluation index for the design. The user's input information can be recognized as a search request by the processor 150.

The processor 150 can filter a plurality of airframe configuration data related to the aircraft according to a criterion condition and select the airframe configuration data in response to the search request (S210).

The plurality of airframe configuration data can be classified by configuration group as described with reference to FIG. 3 and managed in the database unit 142. In the present disclosure, the airframe configuration data can be referred to as the conceptual configuration described with reference to FIG. 3. In the present disclosure, an example in which the selection of the airframe configuration data in operation S210, the generation of the evaluation data in operation S215, and the selection of the conceptual configuration in operation S220 are performed by configuration group can be mainly described. The implementation example according to the present disclosure can be applied to an example in which the airframe configuration data is selected without being divided by configuration group.

As described with reference to FIG. 3, the airframe configuration data can include a plurality of element data that define the configuration of the aircraft. The element data can be the element data of the main configuration described above, the detailed configuration, or the solution. Referring to FIG. 3, the element data can include configuration element data related to the main wing of the aircraft, the tail wing of the aircraft, a structure of the fuselage of the aircraft, a type of coupling between the wing and the fuselage of the aircraft, a type of propulsion component of the aircraft, an arrangement location and number of the propulsion component, and a window type of the aircraft.

The criterion condition can include design infeasibility and the technology maturity.

The design infeasibility can indicate whether design of each of the plurality of element data constituting the airframe configuration data belonging to the configuration group is feasible. From the design infeasibility perspective, the processor 150 can exclude airframe configuration data (or conceptual configurations) of which the design is infeasible from the physical and engineering perspective. For example, Tailless in the configuration of the tail wing, and On Stabilizer or On Tail Boom in a location of a propulsion apparatus can be conceptual configurations (or element data) of which the design is infeasible. Filtering according to the design infeasibility can be performed on each configuration group.

The technology maturity can indicate a technological level related to the development of the element data and practical application of the element data. For example, for the technology maturity, a TRL divided into levels 1 to 9 can be utilized, as described with reference to FIG. 1. The technology maturity can be assigned to each of a plurality of element data. The TRL of each piece of element data (or configuration element) can be technology maturity of the product data and the new technology data stored in the database unit 142.

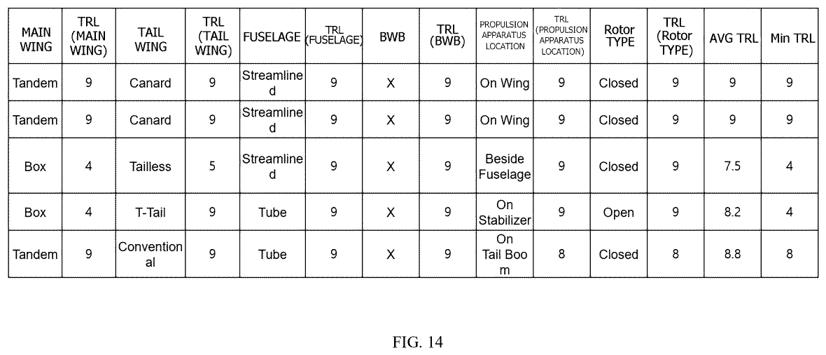

The processor 150 can filter the airframe configuration data including the element data to which technology maturity that does not satisfy minimum technology maturity is assigned. As illustrated in FIG. 14, since development is not easy if a TRL of some components or a configuration element solution is low even when an average TRL value at a system level (or conceptual configuration) is high, a minimum TRL result of the configuration element solution can be utilized instead of an average TRL result. A technology level of the minimum technology maturity can be set to be increased so that the airframe configuration data approximates airframe configuration data of the legacy aircraft. For example, when one configuration family (or configuration group) includes a general conceptual configuration similar to an existing aircraft, the processor 150 can remove the conceptual configuration that is lower than a minimum TRL 5 (which has been verified in a similar environment). When another configuration family uses a new technology compared to an existing aircraft and includes a conceptual configuration corresponding to an unconventional configuration, the processor 150 can use 3 (analysis or experiment is completed for main functions or characteristics of the concept or technology) lower than a TRL of one configuration family as a minimum TRL of the other configuration family. Accordingly, the processor 150 can remove a conceptual configuration lower than TRL 3 for the other configuration family.

In addition to the above-described conditions, the criterion condition can further include a contribution criterion related to the performance evaluation index. The performance evaluation index has been described with reference to FIGS. 1 to 4, and the performance evaluation index utilized in operation S115, such as contribution data for the FoM for each piece of element data of the main configuration, can be used. The contribution data for the FoM for each piece of element data can be stored in the database unit 142, and the contribution data from the database unit 142 can be utilized for filtering according to the performance evaluation index. The processor 150 can select the airframe configuration data that satisfies the contribution criterion by using a combination of the contribution data of the element data primarily assigned according to the performance evaluation index. The contribution criterion can be, for example, designated as a preset value or a predetermined rank.

In operation S115, the extraction of the element data of the main configuration is performed by comparing importance for a single configuration element item, and the filtering according to the performance evaluation index in operation S210 can be performed by calculating and comparing a comprehensive importance score of a solution applied to the entire aircraft. In an example related to contribution data for a conceptual configuration belonging to a specific configuration family and element data of the conceptual configuration, a sum of the contribution data of the respective element data in Straight Main Wing [Score: 0]+Canard [2.33]+Streamlined Fuselage+[3.5]+BWB X [0]+Windowless Design [4]+Closed Thruster [3.33]+(6+) Thruster Below Wing [2.83] can be 15.99 (=0+2.33+3.5+0+4+3.33+2.83).

Since meaningful airframe configuration data is evaluated by filtering rather than all of the generated airframe configuration data in FIG. 3, a burden on computing resources and evaluation tasks can be reduced. In the above example, the filtering is performed in order of the design infeasibility, the technology maturity, and the performance evaluation index, but the order can be changed.

Referring back to FIGS. 4 and 13, the processor 150 can generate evaluation data related to the selected airframe configuration data using the performance evaluation index for the airframe configuration data (S215).

As described above, the performance evaluation index can include the plurality of performance evaluation items in order to evaluate the contribution of the airframe configuration data according to the aircraft design requirements, the aircraft manufacturing process requirements, and the interpreted meanings. For the performance evaluation index, for example, FoM can be utilized. The evaluation data can involve a scoring process. The scoring can be performed by the user or the processor 150 evaluating the performance evaluation index according to the search request and a new determination criterion in an actual design, unlike the filtering in operation S210. The processor 150 can receive detailed evaluation related to a unique performance evaluation index requested by the user in advance, and prepare a performance evaluation index that is used in operation S215. Since top-level requirements considered important in aircraft design differ depending on an actual user or decision maker, and an unexpected conceptual configuration or design result can be derived through a user's subjective evaluation, the process of selecting the conceptual configuration can include generating the evaluation data by utilizing a scoring scheme.

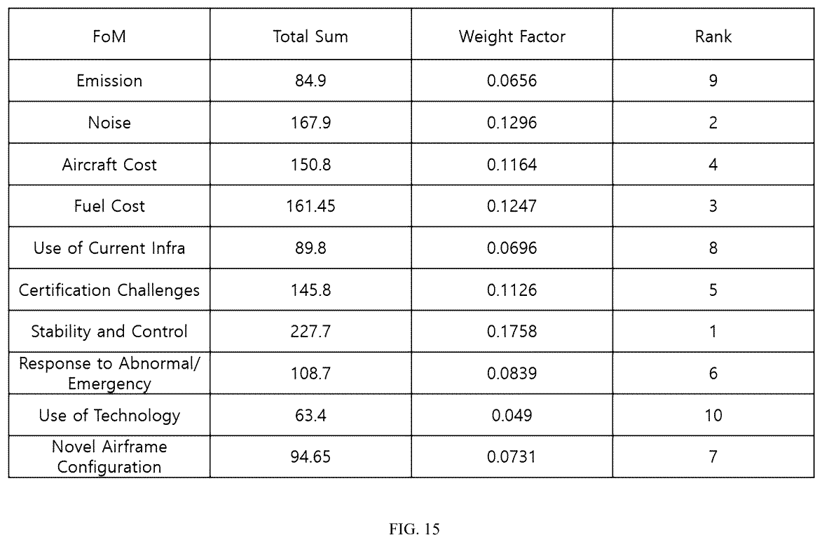

The processor 150 can generate evaluation data by performing weighted summation for a plurality of item evaluation data according to a plurality of performance evaluation items, as illustrated in FIG. 15. FIG. 15 is a diagram illustrating a weight and rank for each item of the performance evaluation index acquired through hierarchical analysis. Referring to FIG. 15, the processor 150 can perform weighted summation for each piece of item evaluation data by using a hierarchical analysis process. For the hierarchical analysis process, pairwise comparison for a plurality of performance evaluation items can be used. The hierarchical analysis process can include setting relative weights between a plurality of performance evaluation items to be compared and performing weighted summation for each piece of item evaluation data. For the hierarchical analysis process, for example, an analytic hierarchy process (AHP) can be used.

Referring back to FIGS. 4 and 13, the processor 150 can select a conceptual configuration of the aircraft from the selected airframe configuration data based on the evaluation data and provide the selected conceptual configuration through the output unit 130 (S220). The conceptual configuration can be selected for each configuration group in an example, or can be selected from the entire configuration group in another example.

A conventional scheme related to the generation and/or selection of the conceptual configurations can be difficult to integrate with an eco-friendly electric propulsion system and apply to an AAM aircraft with an unconventional configuration. In the conventional scheme, only an approach from a performance aspect is performed with the goal of presenting superior target performance compared to competitive or similar aircraft, and data related to the configuration of the aircraft is not collected. In the conventional scheme, since the application of new technologies such as an electric propulsion system, a distributed propulsion system, and a new aircraft design technology is not considered, the advancement of technology cannot be utilized in a conceptual configuration development process. In the conventional scheme, a decision maker can derive extremely subjective results.

The conventional scheme presents components of the aircraft according to subjective opinions of designers without clear criteria or grounds, and a large number of conceptual configurations can be generated through a simple combination. Further, the conventional scheme can lack grounds related to criteria and engineering principles for determining a conceptual configuration of a finally selected aircraft.

According to the present disclosure, the conceptual configuration satisfying design and operational characteristics of a new aircraft manufactured through low-volume, high-mix production is quickly derived so that development costs and development time can be reduced. In addition, in a conceptual configuration of a new air mobility apparatus, such as an AAM, a wide design area can be established from an early stage of development through parameterization, database structuring, process structuring, systemization, and automation, and a new airframe concept solution can be quickly searched for and determined.

According to the present disclosure, it is possible to provide a method and apparatus for generating a conceptual configuration for an aircraft that reduces development costs and development time by quickly deriving the conceptual configuration satisfying design and operational characteristics of a new aircraft manufactured through low-volume, high-mix production.

Specifically, in a conceptual configuration of a new air mobility apparatus, such as an AAM, a wide design area is established from an early stage of development through parameterization, database structuring, process structuring, systemization, and automation, and a new airframe concept solution can be quickly searched for and determined.

The effects that can be obtained from the present disclosure are not limited to the effects mentioned above, and other effects that are not mentioned can be clearly understood by those skilled in the art from the description.

While the example methods of the present disclosure described above are represented as a series of operations for clarity of description, it is not intended to limit the order in which the steps are performed, and the steps can be performed simultaneously or in different order. In order to implement the method according to the present disclosure, the described steps can further include other steps, can include remaining steps except for some of the steps, or can include other additional steps except for some of the steps.

The various implementations of the present disclosure are not a list of all possible combinations and are intended to describe representative aspects of the present disclosure, and the matters described in the various implementations can be applied independently or in combination of two or more.

In addition, various implementations of the present disclosure can be implemented in hardware, firmware, software, or a combination thereof. In the case of implementing the present disclosure by hardware, the present disclosure can be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the disclosure includes software or machine-executable commands (e.g., an operating system, an application, firmware, a program, etc.) for enabling operations according to the methods of various implementations to be executed on an apparatus or a computer, a non-transitory computer-readable medium having such software or commands stored thereon and executable on the apparatus or the computer.

What is claimed is:

1. A method for generating a conceptual design for a mobility apparatus, comprising:
generating problem definition data based on a requirement specification of a user;
generating function data according to functional decomposition for a mission of the mobility apparatus based on the requirement specification and the problem definition data;
extracting element data of a main configuration of the mobility apparatus based on (i) design concept data that have been searched for based on the function data and (ii) external data; and
generating matrix data including airframe configuration data of the mobility apparatus based on a combination of the element data of the main configuration.

2. The method of claim 1, wherein the problem definition data comprises:
a design requirement and a manufacturing process requirement of the mobility apparatus that are generated based on analyzing the requirement specification of the user; and
a performance evaluation index of the airframe configuration data for each of the design requirement and the manufacturing process requirement, wherein the performance evaluation index indicates a contribution of the airframe configuration data to each of the design requirement and the manufacturing process requirement.

3. The method of claim 1, wherein generating the problem definition data comprises:
based on the airframe configuration data corresponding to the mobility apparatus that is different in design and operation from a legacy aircraft, generating the problem definition data from the requirement specification according to at least one of (i) reduction of hazardous substance emission, (ii) low noise, (iii) certification challenges of the mobility apparatus, (iv) use of new technology, and (v) a novel airframe configuration.

4. The method of claim 1, wherein the mission defined in the function data is classified based on at least one of a flight section or a flight behavior of the mobility apparatus, and
wherein the function data comprises (i) functions of the mobility apparatus according to the mission, (ii) configuration elements of airframe components in the mobility apparatus related to the functions, and (iii) technology elements related to the configuration elements.

5. The method of claim 1, wherein the external data comprises a database including at least one of competitive aircraft data, technology data, product data, or configuration classification data,
wherein the competitive aircraft data comprises configuration of a competitive aircraft, a specification of the competitive aircraft, performance of the competitive aircraft, technology elements applied to the competitive aircraft, or development plan data of the competitive aircraft,
wherein the technology data comprises technology data available for the mobility apparatus,
wherein the product data comprises product information related to propulsion components of the mobility apparatus, and
wherein the configuration classification data comprises configuration information related to configuration elements of airframe components.

6. The method of claim 5, wherein the database interconnects external data that satisfy the functions of the aircraft according to the mission and that include the competitive mobility apparatus data, the technology data, the product data, and the configuration classification data.

7. The method of claim 1, wherein extracting the element data of the main configuration comprises extracting the element data of the main configuration from the design concept data and the external data based on contribution data according to a performance evaluation index provided in the problem definition data, and
wherein the contribution data comprises a contribution to the performance evaluation index for each configuration element of the design concept data and the external data.

8. The method of claim 1, wherein generating the matrix data comprises:
generating examination data by combining evaluations of the element data of the main configuration based on a performance evaluation index provided in the problem definition data; and
selecting the airframe configuration data from the combination of the element data of the main configuration based on the examination data according to the performance evaluation index.

9. The method of claim 1, further comprising:
after generating the matrix data, classifying the airframe configuration data of the matrix data based on a configuration group, and outputting the airframe configuration data.

10. The method of claim 9, wherein classifying the airframe configuration data comprises:
classifying the airframe configuration data (i) based on a configuration similarity between pieces of the airframe configuration data, or (ii) based on configurations that satisfy a predetermined condition in a dissimilarity between the configurations of the airframe configuration data.

11. An apparatus configured to generate a conceptual design for a mobility apparatus, the apparatus comprising:
at least one processor; and
a non-transitory memory coupled to the at least one processor and storing instructions that, based on being executed by the at least one processor, perform operations comprising:
generating problem definition data based on a requirement specification of a user,
generating function data according to functional decomposition for a mission of the mobility apparatus based on the requirement specification and the problem definition data,
extracting element data of a main configuration of the mobility apparatus based on (i) design concept data that have been searched for based on the function data and (ii) external data, and
generating matrix data including airframe configuration data of the mobility apparatus based on a combination of the element data of the main configuration.

12. The apparatus of claim 11, wherein the problem definition data comprises:
a design requirement and a manufacturing process requirement of the mobility apparatus that are generated based on analyzing the requirement specification of the user; and
a performance evaluation index of the airframe configuration data for each of the design requirement and the manufacturing process requirement, wherein the performance evaluation index indicates a contribution of the airframe configuration data to each of the design requirement and the manufacturing process requirement.

13. The apparatus of claim 11, wherein generating the problem definition data comprises:
based on the airframe configuration data corresponding to the mobility apparatus that is different in design and operation from a legacy aircraft, generating the problem definition data from the requirement specification according to at least one of (i) reduction of hazardous substance emission, (ii) low noise, (iii) certification challenges of the mobility apparatus, (iv) use of new technology, and (v) a novel airframe configuration.

14. The apparatus of claim 11, wherein the mission defined in the function data is classified based on at least one of a flight section or a flight behavior of the mobility apparatus, and
wherein the function data comprises (i) functions of the mobility apparatus according to the mission, (ii) configuration elements of airframe components in the mobility apparatus related to the functions, and (iii) technology elements related to the configuration elements.

15. The apparatus of claim 11, wherein the external data comprises a database including at least one of competitive aircraft data, technology data, product data, or configuration classification data,
wherein the competitive aircraft data comprises configuration of a competitive aircraft, a specification of the competitive aircraft, performance of the competitive aircraft, technology elements applied to the competitive aircraft, or development plan data of the competitive aircraft,
wherein the technology data comprises technology data available for the mobility apparatus,
wherein the product data comprises product information related to propulsion components of the mobility apparatus, and
wherein the configuration classification data comprises configuration information related to configuration elements of airframe components.

16. The apparatus of claim 15, wherein the database interconnects external data that satisfy the functions of the mobility apparatus according to the mission and that include the competitive aircraft data, the technology data, the product data, and the configuration classification data.

17. The apparatus of claim 11, wherein extracting the element data of the main configuration comprises extracting the element data of the main configuration from the design concept data and the external data based on contribution data according to a performance evaluation index provided in the problem definition data, and
wherein the contribution data comprises a contribution to the performance evaluation index for each configuration element of the design concept data and the external data.

18. The apparatus of claim 11, wherein generating the matrix data comprises:
generating examination data by combining evaluations of the element data of the main configuration based on a performance evaluation index provided in the problem definition data; and
selecting the airframe configuration data from the combination of the element data of the main configuration based on the examination data according to the performance evaluation index.

19. The apparatus of claim 11, wherein the operations further comprise:
after generating the matrix data, classifying the airframe configuration data of the matrix data based on a configuration group, and outputting the airframe configuration data.

20. The apparatus of claim 19, wherein classifying the airframe configuration data comprises:
classifying the airframe configuration data (i) based on a configuration similarity between pieces of the airframe configuration data, or (ii) based on configurations that satisfy a predetermined condition in a dissimilarity between the configurations of the airframe configuration data.
